(19) United States
(12) Patent Application Publication
(10) Pub. No.: US 2025/0011158 A1
(43) Pub. Date: Jan. 9, 2025

(54) MEMS Microphone

(71) Applicant: AAC ACOUSTIC TECHNOLOGIES (SHENZHEN) CO., LTD., Shenzhen (CN)

(72) Inventors: Xingfu Chen, Shenzhen (CN); Zhiyuan Chen, Shenzhen (CN); Tangyu Zhang, Shenzhen (CN)

(21) Appl. No.: 18/399,742

(22) Filed: Dec. 29, 2023

Related U.S. Application Data
(63) Continuation of application No. PCT/CN2023/105942, filed on Jul. 5, 2023.

(51) Int. Cl. B81B 3/00

(52) U.S. Cl. CPC B81B 3/0075; B81B 2201/0257; B81B 2203/0127; B81B 2203/0338; B81B 2203/0353; B81B 2207/015

(57) ABSTRACT

The present disclosure discloses a MEMS microphone including a shell, a substrate assembled with the shell for forming a receiving space, an ASIC Die, a MEMS Die including a diaphragm and a back plate, and an elastic member. The diaphragm divides the receiving space into a front chamber and a rear chamber, the substrate comprises a first acoustic hole, a second acoustic hole, a connecting channel, and a ventilation hole, the MEMS Die covers the first acoustic hole which is communicating with the front chamber, the ventilation hole is communicating with the connecting channel and the rear chamber, the elastic member covering the ventilation hole is used for opening or closing the ventilation hole. Compared with the related art, a MEMS microphone disclosed by the present disclosure could have with high blowout resistance.

### FIELD OF THE PRESENT DISCLOSURE

The present disclosure relates to microphones, in particular to a micro-electro-mechanical system (MEMS) microphone.

### DESCRIPTION OF RELATED ART

MEMS (Microelectro Mechanical Systems) microphones, which are MEMS microphones manufactured based on MEMS sensor technology, have improved noise cancellation performance, good RF performance, and EMI suppression, and are widely used in a variety of electronic products such as smartphones, in-line headsets, tablets, and notebooks.

A MEMS microphone in the related art includes a shell, a substrate covered the shell to form a receiving cavity, and an ASIC Die and a MEMS Die located in the receiving room. The MEMS Die is accommodated on the substrate, the MEMS Die divides the receiving cavity into a front chamber and a back chamber. The substrate is provided a through hole communicating with the front chamber, after the atmospheric pressure enters through the through hole, it takes some time for the air pressure in the front and back chamber to be balanced, so it is easy to damage the diaphragm of the MEMS chip, and the MEMS microphone has a weak resistance to blowing.

Thus, it is necessary to provide a novel MEMS microphone to solve the problem.

### SUMMARY OF THE DISCLOSURE

The present disclosure is to provide a MEMS microphone with high blowout resistance.

For achieving the object mentioned above, the disclosure provides a MEMS microphone including a shell, a substrate assembled with the shell for forming a receiving space, an ASIC Die accommodated in the receiving space, and a MEMS Die including a diaphragm and a back plate apart from the diaphragm. The MEMS Die is accommodated in the receiving space and mounted on the substrate. The diaphragm divides the receiving space into a front chamber and a rear chamber, the substrate includes an upper surface connected with the MEMS Die and a lower surface opposite to the upper surface, the substrate comprises a first acoustic hole extending downwardly from the upper surface and not penetrating the lower surface, a second acoustic hole extending upwardly from the lower surface and not penetrating the upper surface, a connecting channel located between the upper surface and the lower surface and communicating with the first acoustic hole and the second acoustic hole, and a ventilation hole extending downwardly from the upper surface and not penetrating the lower surface, the MEMS Die covers the first acoustic hole which is communicating with the front chamber, the ventilation hole is communicating with the connecting channel and the rear chamber, the ventilation hole and the second acoustic hole are laterally spaced apart; the MEMS microphone is further provided with an elastic member covering the ventilation hole, the elastic member is used for opening or closing the ventilation hole.

Further, the elastic member is connected with the upper surface of the substrate.

Further, the elastic member comprises a fixed portion connected with the upper surface of the substrate and a resilient portion covering the ventilation.

Further, the first acoustic hole and the second acoustic hole are laterally spaced apart.

Further, a projection of the second acoustic hole on the upper surface and the ventilation hole are respectively located two sides of the MEMS Die.

Further, the substrate is a laminated circuit board comprising a first circuit board connected to the MEMS Die, a second circuit board spaced apart from the first circuit board, and a third circuit board located between the first circuit board and the second circuit board, the third circuit board is a hollow annular structure, the first acoustic hole and the ventilation hole penetrate the first circuit board, the second acoustic hole penetrates the second circuit board.

Further, the diaphragm is closer to the substrate than the back plate.

### BRIEF DESCRIPTION OF THE DRAWINGS

Many aspects of the exemplary embodiment can be better understood with reference to the following drawings. The components in the drawing are not necessarily drawn to scale, the emphasis instead being placed upon clearly illustrating the principles of the present disclosure.

FIG. 1 is a cross-sectional view of a MEMS microphone in accordance with an exemplary embodiment of the present disclosure.

### DETAILED DESCRIPTION OF THE EXEMPLARY EMBODIMENTS

The present disclosure will hereinafter be described in detail with reference to exemplary embodiments. To make the technical problems to be solved, and technical solutions and beneficial effects of the present disclosure more apparent, the present disclosure is described in further detail together with the FIGURE and the embodiment. It should be understood the specific embodiment described hereby is only to explain the disclosure, not intended to limit the disclosure.

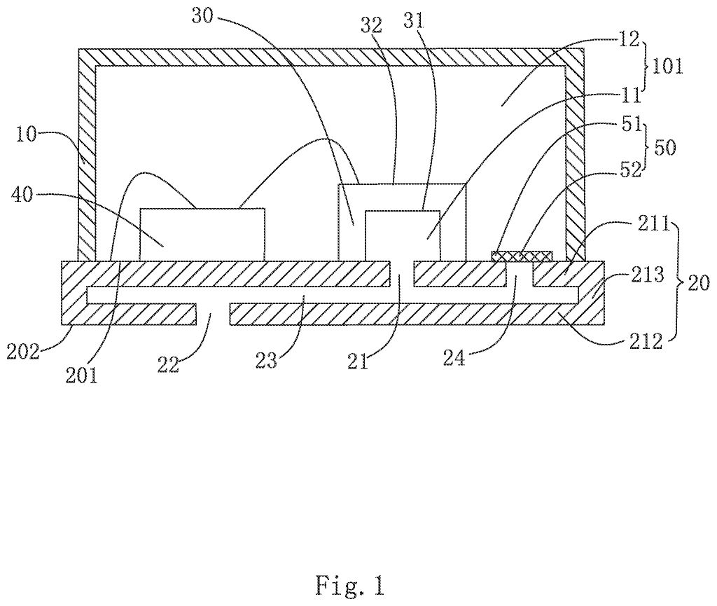

Referring to FIG. 1, the present disclosure discloses a MEMS microphone 100, which includes a shell 10, a substrate 20 assembled with the shell 10 for forming a receiving space 101, and an ASIC Die 40 and a MEMS Die 30 accommodated in the receiving space 101. The MEMS Die 30 is connected with the substrate 20. The MEMS Die 30 includes a diaphragm 31 and a back plate 32 apart from the diaphragm 31, the MEMS Die 30 and the ASIC Die 40 form a capacitive structure, and the diaphragm 31 divides the receiving space 101 into a front chamber 11 and a rear chamber 12. In this embodiment, the diaphragm 31 is closer to the back plate 32 than the substrate 20. In the other embodiment, the back plate could be closer to the diaphragm than the substrate.

The substrate 20 includes an upper surface 201 connected with the MEMS Die 30 and a lower surface 202 opposite to the upper surface 201, the substrate 30 is provided with a first acoustic hole 21 extending downwardly from the upper surface 201 and not penetrating the lower surface 202, a second acoustic hole 22 extending upwardly from the lower surface 202 and not penetrating the upper surface 201, and a connecting channel 23 located between the upper surface 201 and the lower surface 202 and communicating with the first acoustic hole 21 and the second acoustic hole 22. The MEMS Die 30 covers the first acoustic hole 21 and communicates with the front chamber 11. The first acoustic hole 21 and the second acoustic hole 22 are provided at lateral intervals, i.e., the first acoustic hole 21 and the second acoustic hole 22 are provided at staggered intervals, which can prevent dust from an outside from falling onto the MEMS Die 30, and also play a buffering role for the impact of airflow from the outside, which improves the reliability of the product.

In this embodiment, the substrate 20 further includes a ventilation hole 24 extending downwardly from the upper surface 201 and not penetrating the lower surface 202, the ventilation hole 24 communicates with the connecting channel 23 and the rear chamber 12. The MEMS microphone 100 is further provided with an elastic member 50 covering the ventilation hole 24, the elastic member 50 is used for opening or closing the ventilation hole 24. When the external airflow passes through the second acoustic hole 22 and the connecting channel 23, the elastic member 50 could open so that the connecting channel 23 communicates with the front chamber 12 through the ventilation hole 24 to balance the air pressure between the front and rear chambers at the same time, so as to reduce the impact of the external airflow on the MEMS die 30. In addition, the ventilation hole 24 and the second acoustic hole 22 are provided at lateral intervals, i.e., the ventilation hole 24 and the second acoustic hole 22 are provided at staggered intervals, which can reduce the direct impact of external airflow on the elastic member 50 and increases the life of the elastic member 50.

The elastic member 50 is connected with the upper surface 201 of the substrate 20, the elastic member 50 includes a fixed portion 51 connected with the upper surface 201 of the substrate 20 and a resilient portion 52 covering the ventilation hole 24. The fixed portion 51 is a fixed end, and the resilient portion 51 is a free end, the resilient portion 51 is not fixed to the substrate 20, the fixed portion 51 and the resilient portion 50 are integrally disposed, and the elastic member 50 may be a resilient silica gel or a thin metal sheet.

When the sound from the outside enters the connection channel 23 through the second acoustic hole 22 and subsequently enters the first acoustic hole 21 to reach the MEMS Die 30, the MEMS Die 30 converts the acoustic signals into electrical signals, and the ASIC Die 40 receives the electrical signals from the MEMS Die 30 and processes the electrical signals and outputs them externally. In this embodiment, a projection of the second acoustic hole 22 on the upper surface 201 and the ventilation hole 24 are located on both sides of the MEMS Die 30, i.e., the first acoustic hole 21 is closer to the second acoustic hole 22 than the ventilation hole 24, which may enable the acoustic signal to be picked up by the MEMS Die 30 through the first acoustic hole 21, and prevent the acoustic signal from entering the rear chamber 12 directly from the ventilation hole 24, which may affect the reliability of the product.

The substrate 20 is a laminated circuit board comprising a first circuit board 211 connected to the MEMS Die 30, a second circuit board 212 spaced apart from the first circuit board 211, and a third circuit board 213 located between the first circuit board 211 and the second circuit board 212, the third circuit board 213 is a hollow annular structure, the first acoustic hole 21 and the ventilation hole 24 penetrate the first circuit board 211, the second acoustic hole 22 penetrates the second circuit board 212. In other embodiments, cavities may also be dug directly into the interior of the substrate.

Due to the provision of the ventilation hole 24 and elastic member 50 on the substrate 20, the MEMS microphone 100 could open the ventilation holes 24 to balance the air pressure in the front and rear chambers in a timely manner when needed, which cushion the impact of the air pressure on the diaphragm 31 of the MEMS Die 30.

It is to be understood, however, that even though numerous characteristics and advantages of the present exemplary embodiment have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms where the appended claims are expressed.

What is claimed is:

1. A MEMS microphone, comprising:
a shell;
a substrate assembled with the shell for forming a receiving space;
an ASIC Die accommodated in the receiving space; and
a MEMS Die including a diaphragm and a back plate apart from the diaphragm, accommodated in the receiving space and mounted on the substrate; wherein
the diaphragm divides the receiving space into a front chamber and a rear chamber, the substrate includes an upper surface connected with the MEMS Die and a lower surface opposite to the upper surface, the substrate comprises a first acoustic hole extending downwardly from the upper surface and not penetrating the lower surface, a second acoustic hole extending upwardly from the lower surface and not penetrating the upper surface, a connecting channel located between the upper surface and the lower surface and communicating with the first acoustic hole and the second acoustic hole, and a ventilation hole extending downwardly from the upper surface and not penetrating the lower surface, the MEMS Die covers the first acoustic hole which is communicating with the front chamber, the ventilation hole is communicating with the connecting channel and the rear chamber, the ventilation hole and the second acoustic hole are laterally spaced apart;
the MEMS microphone is further provided with an elastic member covering the ventilation hole, the elastic member is used for opening or closing the ventilation hole.

2. The MEMS microphone as described in claim 1, wherein the elastic member is connected with the upper surface of the substrate.

3. The MEMS microphone as described in claim 1, wherein the elastic member comprises a fixed portion connected with the upper surface of the substrate and a resilient portion covering the ventilation.

4. The MEMS microphone as described in claim 1, wherein the first acoustic hole and the second acoustic hole are laterally spaced apart.

5. The MEMS microphone as described in claim 1, wherein a projection of the second acoustic hole on the upper surface and the ventilation hole are respectively located two sides of the MEMS Die.

6. The MEMS microphone as described in claim 1, wherein the substrate is a laminated circuit board comprising a first circuit board connected to the MEMS Die, a second circuit board spaced apart from the first circuit board, and a third circuit board located between the first circuit board and the second circuit board, the third circuit board is a hollow annular structure, the first acoustic hole and the ventilation hole penetrate the first circuit board, the second acoustic hole penetrates the second circuit board.

7. The MEMS microphone as described in claim 1, wherein the diaphragm is closer to the substrate than the back plate.
